(19) United States
(12) Patent Application Publication
(10) Pub. No.: US 2009/0280249 A1
(43) Pub. Date: Nov. 12, 2009

(54) PROCESS AND APPARATUS FOR FLASH EVAPORATION

(75) Inventor: Hisashi TAKAHASHI, Odawara-shi (JP)

Correspondence Address: YOUNG & THOMPSON, 209 Madison Street, Suite 500, ALEXANDRIA, VA, 22314, US

(73) Assignee: FUJIFILM CORPORATION, Tokyo (JP)

(21) Appl. No.: 12/433,298

(22) Filed: Apr. 30, 2009

(30) Foreign Application Priority Data
Apr. 30, 2008 (JP) 2008-118976

(51) Int. Cl. C23C 16/00

(52) U.S. Cl. 427/255.28; 118/718

(57) ABSTRACT

A flash evaporation apparatus includes: a reaction chamber; a drum to support a continuously conveyed film; a plurality of evaporators; monomer tanks which are connected to the respective evaporators and hold different kinds of liquid monomers therein; liquid feeding pumps for feeding the monomers from the monomer tanks to the evaporators; a merging section for merging vaporized monomers discharged from the evaporators; a mixer connected to the merging section; and a nozzle connected to the mixer. Accordingly, the flash evaporation apparatus can vaporize different kinds of monomers using separate evaporators and mix the monomers.

### BACKGROUND OF THE INVENTION

1. Field of the Invention

The present invention relates to a process and an apparatus for flash evaporation, more particularly to a process and an apparatus for flash evaporation for the purpose of forming a monomer layer on a continuously traveling substrate.

2. Description of the Related Art

As a process for forming a monomer layer on a continuously traveling substrate, there is heretofore known a flash evaporation process. Japanese National Publication of International Patent Application No. 2001-508089 discloses a process in which an acrylate monomer layer is deposited on a continuously traveling substrate by use of a flash evaporator and, after polymerizing the acrylate monomer layer, a metal coating is provided thereon. The flash evaporator is an apparatus for evaporating a liquid monomer and the vaporized monomer supplied from the flash evaporator condenses on the substrate which is cooled and forms a monomer layer.

### SUMMARY OF THE INVENTION

Incidentally, the monomers have different vapor pressures and polymerizability depending on the molecular weight, number of functional groups, and the like. On the other hand, from a viewpoint of quality improvement, there is a strong demand for a plurality of monomers with different characteristics to be used blended.

However, in the above-mentioned process, there is a problem that the monomer cannot be fed steadily because the monomer evaporates inside the capillary or the monomer polymerizes inside the capillary. Therefore, there are many restrictions in selecting the monomers and it has not been easy to mix the monomers.

Also, in the above-mentioned process, when operated for a long time, a specific monomer remains and deposits inside the evaporator. Once the monomer begins to deposit on the inner wall of the evaporator, the temperature of the wall surface is caused to decrease. This makes flash evaporation not to be carried out sufficiently and evaporation efficiency drops, resulting in rapid acceleration of the monomer deposition on the inner wall. As a result, the rate of film formation drops sharply and a problem arises that the distribution of film thickness worsens.

The present invention was made in view of such circumstances and its object is to provide a process and apparatus for flash vaporization, which makes it possible to mix a plurality of vaporized monomers and supply the mixture to the substrate.

In order to attain the object, a method for flash evaporation according to a first aspect of the present invention, comprises: continuously conveying a substrate; feeding a plurality of kinds of monomers prepared in liquid states to separate evaporators; vaporizing the respective monomers in the separate evaporators and discharging the respective vaporized monomers from the evaporators; and merging the vaporized monomers and feeding the merged monomers to the substrate for deposition.

According to the method according to the first aspect of the present invention, a plurality of kinds of monomers are vaporized by separate evaporators and merged, and then the monomers are deposited by flash evaporation on the substrate. Therefore, the monomers can be mixed relatively easily without limitation from monomers.

Preferably, the method of flash evaporation according to the first aspect further comprises mixing the monomers after the merging.

Because a plurality of kinds of vaporized monomers are mixed after being merged, efficient mixing becomes possible.

In the method for flash evaporation according to the first aspect, preferably the mixing is performed using a static mixer or a dynamic mixer.

The plurality of kinds of vaporized monomers can be mixed by a static mixer or a dynamic mixer.

In order to attain the aforementioned object, an apparatus for flash evaporation according to a second aspect of the present invention, comprises: a reaction chamber; a drum disposed inside the reaction chamber to support a continuously conveyed substrate; a first evaporator; a first tank which is connected to the first evaporator and holds a first monomer in liquid state therein; a first pump for feeding the first monomer from the first tank to the first evaporator; a second evaporator; a second tank which is connected to the second evaporator and holds a second monomer whose kind is different from that of the first monomer, in liquid state therein; a second pump for feeding the second monomer from the second tank to the second evaporator; a merging section for merging the vaporized first and second monomers which are discharged from the first and second evaporators; and a nozzle disposed facing the drum and connected to the merging section.

Preferably, the apparatus for flash evaporation according to the second aspect of the present invention further comprises a mixer connected between the nozzle and the merging section.

In the apparatus for flash evaporation according to the second aspect, preferably the mixer is a static mixer or a dynamic mixer.

Thus, in the method and apparatus for flash evaporation according to the aspects of the present invention, a plurality of kinds of monomers are vaporized by separate evaporators and merged, and then the monomers are deposited by flash evaporation on the substrate. Therefore, the monomers can be mixed relatively easily.

### BRIEF DESCRIPTION OF THE DRAWINGS

FIG. 1 is a schematic diagram showing an example of the apparatus for flash evaporation according to the present invention.

### DETAILED DESCRIPTION OF THE PREFERRED EMBODIMENTS

Hereinafter, the preferred embodiment of the present invention will be described by referring to the accompanying drawing. Even though the present invention is described by the following preferable embodiment, modifications may be made by many techniques without departing from the scope of the present invention and embodiments other than the present embodiment may be utilized. Accordingly, all modifications made in the scope of the present invention are included in the scope of claims.

Also, in the present description, the numerical range indicated by using “to” means a range which contains the values described before and after “to”.

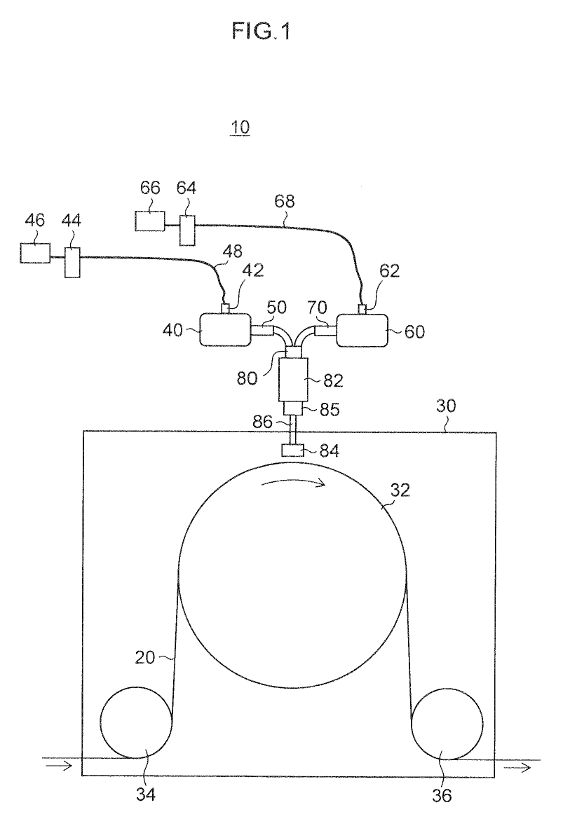

FIG. 1 is a schematic diagram showing an example of the apparatus for flash evaporation. A flash evaporation apparatus 10 is an apparatus by which a monomer layer is formed and cured on a film 20 which travels continuously as a substrate, namely an apparatus for forming a monomer layer on the film 20 by a so-called Roll to Roll process.

The flash evaporation apparatus 10 comprises a reaction chamber 30, the inner pressure of which can be adjusted. The inner pressure of the reaction chamber 30 can be controlled in a range of 0.1 Torr to 10 Torr. Inside the reaction chamber 30, there are disposed a drum 32 to support the continuously traveling film 20 and guide rollers 34 and 36 positioned at an upstream side and a downstream side of the drum 32. By the guide rollers 34 and 36, the film 20 conveyed into the reaction chamber 30 is guided to the drum 32. The drum 32 comprises a temperature control unit which is not shown and, by using the same, the surface of the drum 32 can be controlled, for example, in a range of −20° C. to 80° C.

Outside the reaction chamber 30, there are installed two evaporators 40 and 60. To the evaporator 40, there are connected through a capillary 48 an ultrasonic nozzle 42, a liquid feeding pump 44, and a monomer tank 46. In the same manner, to the evaporator 60 are connected through a capillary 68 an ultrasonic nozzle 62, a liquid feeding pump 64, and a monomer tank 66.

The monomer tanks 46 and 66 are tanks for holding the liquid monomers and, in the present embodiment, the monomer tanks 46 and 66 store different monomers. The liquid feeding pumps 44 and 64 are pumps which supply the liquid monomers kept in the monomer tanks 46 and 66 to the evaporators 40 and 60. The ultrasonic nozzles 42 and 62 are apparatuses for atomizing the liquid monomers, fed by the liquid feeding pumps 44 and 64, to appropriate particle sizes and, through these, the monomers are supplied to the evaporators 40 and 60.

The evaporators 40 and 60 are apparatuses which vaporize the atomized monomers supplied from nozzles 42 and 62 by holding the inner wall temperature to 200° C. to 300° C. The inner wall temperature can be adjusted appropriately depending on the monomers used. On the evaporators 40 and 60, there are disposed vents 50 and 70 for discharging the vaporized monomers. The vents 50 and 70 are connected to the merging section 80 in order to merge the vaporized monomers discharged from the respective evaporators 40 and 60.

In order to mix the vaporized monomers, there is disposed a mixer 82 on the tip of the merging section 80. As the mixer 82, a static mixer or a dynamic mixer can be suitably used. The static mixer comprises inside a cylindrical pipe, for example, an element in a form of a rectangular plate twisted 180° and does not have any drive section. Two vaporized monomers are mixed by their passing through the element.

The dynamic mixer includes, for example, a motor-driven, forced stirring blade in a cylindrical pipe. By changing the output of the motor, mixing output is set at will to realize agitation stirring.

In addition, the static mixer can be used suitably as the mixer because of its characteristics such as that its structure is simple without a drive section, that various surface treatments and the like can be easily provided in order to prevent sticking of the monomers to the element, that efficient mixing is possible with low viscosity gases, and that stirring can be accelerated easily by multi-stage installation of the same.

To the tip of the mixer 82, there is connected a nozzle 84. The nozzle 84 is disposed at a position which faces the drum 32. The nozzle 84 supplies the two vaporized monomers mixed by the mixer 82 onto the traveling film 20.

Next, a method for forming a monomer layer on the surface of the film 20 by use of the flash evaporation apparatus 10 described above will be described with reference to FIG. 1. The film 20 which has undergone various treatments is conveyed into the reaction chamber 30. The temperature inside the reaction chamber 30 is adjusted beforehand to −20° C. to 80° C. The film 20 is guided to the drum 32 by the guide roller 34 inside the reaction chamber 30.

The different liquid monomers, stored in the monomer tanks 46 and 66, are fed by the liquid feeding pumps 44 and 64 to the evaporators 40 and 60 through the capillaries 48 and 68. The liquid monomers are atomized by the ultrasonic nozzles 42 and 62 to an appropriate particle size and fed to the evaporators 40 and 60. The monomers fed are vaporized by the evaporators 40 and 60, and the respective vaporized monomers are discharged from vents 50 and 70 and merged in the merging section 80. Thereafter, the respective vaporized monomers are mixed by the mixer 82 and flash evaporated from the nozzle 84 onto the continuously traveling film 20.

The temperatures of the evaporators 40 and 60 and the pipes disposed before merging (from 50 and 70 to 80) are controlled each independently to temperatures suitable for the respective monomers. The temperatures of the pipes 85 and 86 and the nozzle 84, disposed after merging, are set in a range higher than the lowest temperature among temperatures at which the respective monomers begin to condense and polymerize and lower than the lowest temperature among decomposition temperatures of the respective monomers. It is preferable to branch the pipe 86 disposed after the merging section into several pipes in the direction of drum axis (the width direction of the film). This is in order to flash evaporate the monomers evenly from the nozzle 84 onto the continuously traveling film 20.

The monomers flash evaporated onto the film 20 condense and deposit on the surface of the film 20 supported by the drum 32, which is cooled, to form a monomer layer. The film having a monomer layer formed thereon is guided by the guide roller 36 and is conveyed from the reaction chamber 30 to the next process. Thereafter, for example, an inorganic film can be formed by vacuum coating on the film having a monomer layer formed. An embodiment of the present invention has been described based on FIG. 1. However, the present invention is not limited to this embodiment. For example, there may be employed configurations where the inorganic film is formed at an upstream side of the reaction chamber 30 or the inorganic film is formed on the drum 32 at an upstream side or a downstream side.

In the present invention, there is no particular restriction on the substrate on which the monomer layer is formed. Various base films used for functional films such as a gas barrier film, an optical film, and a protective film are all applicable, provided that forming and curing a monomer layer is possible thereon, examples including various resin films such as PET, PEN, TAC, and PC films and various metal sheets such as an aluminum sheet.

In the present invention, preferable monomers which can be used for forming a monomer layer include acrylates, methacrylates, and commercial adhesives. That is, in the present invention, the monomer is preferably one which comprises as the main component a polymer obtained by polymerizing acrylate monomers and/or methacrylate monomers having ethylenic unsaturated bonds. Especially, when acrylate monomers and/or methacrylate monomers are used, it is preferable to use those having a molecular weight of 700 or less, above all, especially 150 to 600, because inconveniences encountered in a vacuum, which will be described later, can be avoided.

The commercial adhesives include Epo-Tek Series products produced by Daizo Corporation (Nichimoly Division), XNR-5000 Series products produced by Nagase Chemtex Corporation, 3000 Series products produced by ThreeBond Co., Ltd., and the like.

Preferable examples of the acrylates and methacrylates include, for example, the compounds described in U.S. Pat. Nos. 6,083,628 and 6,214,422. A part of these are exemplified in the following.

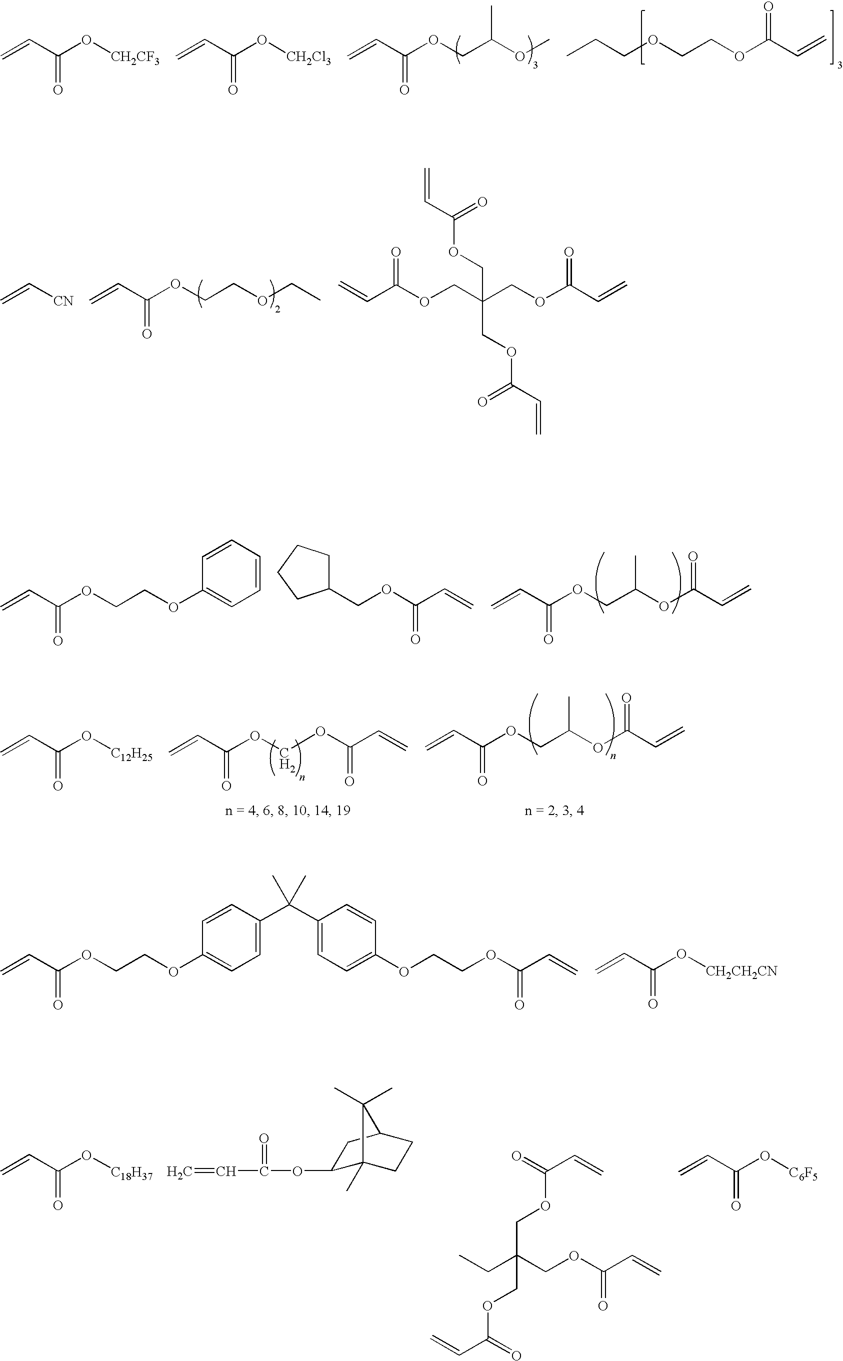

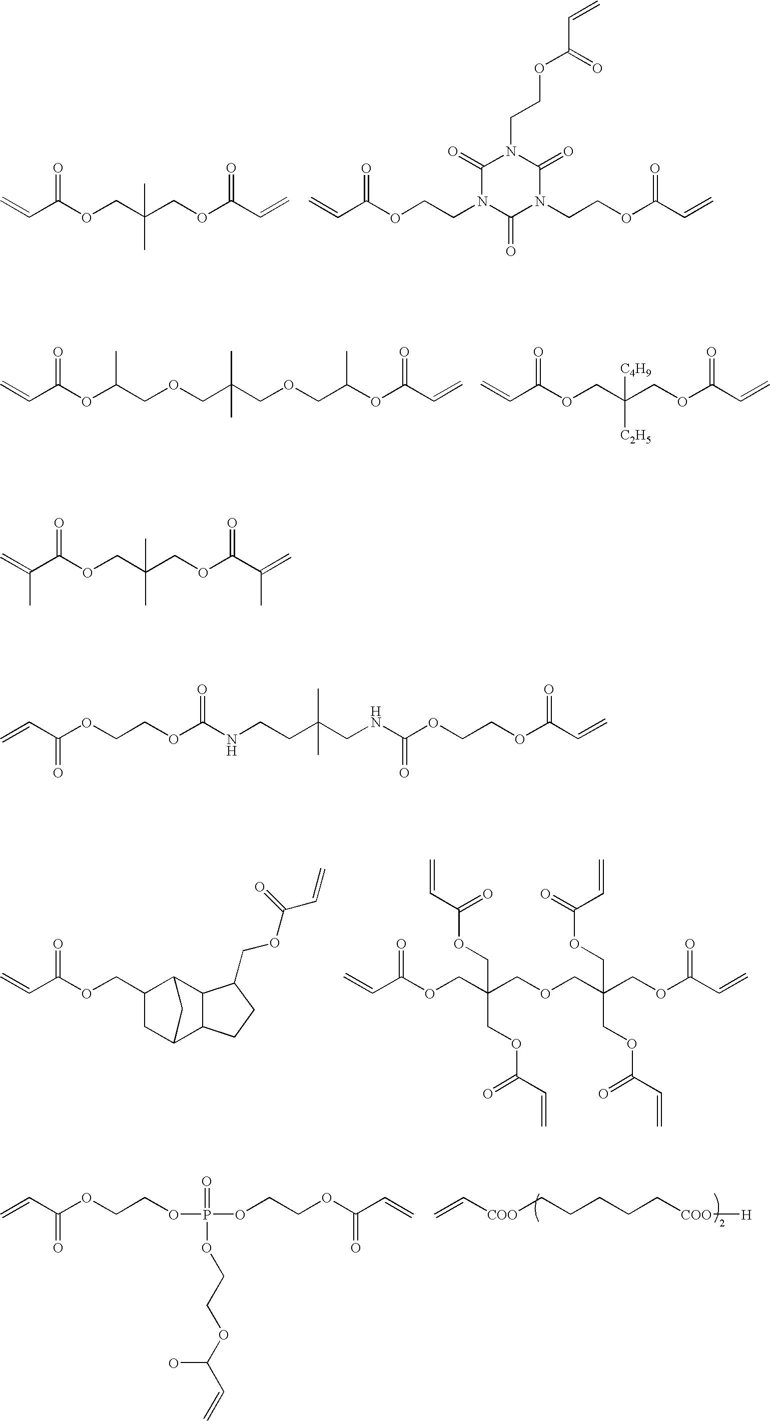

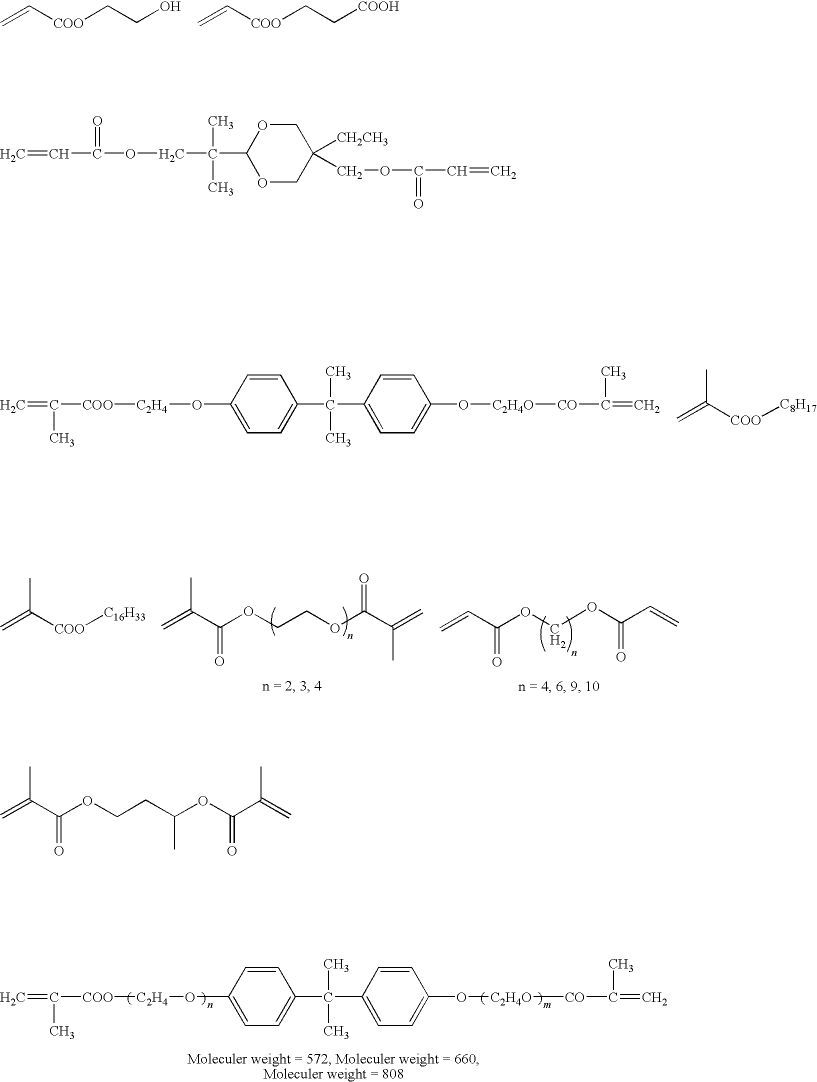

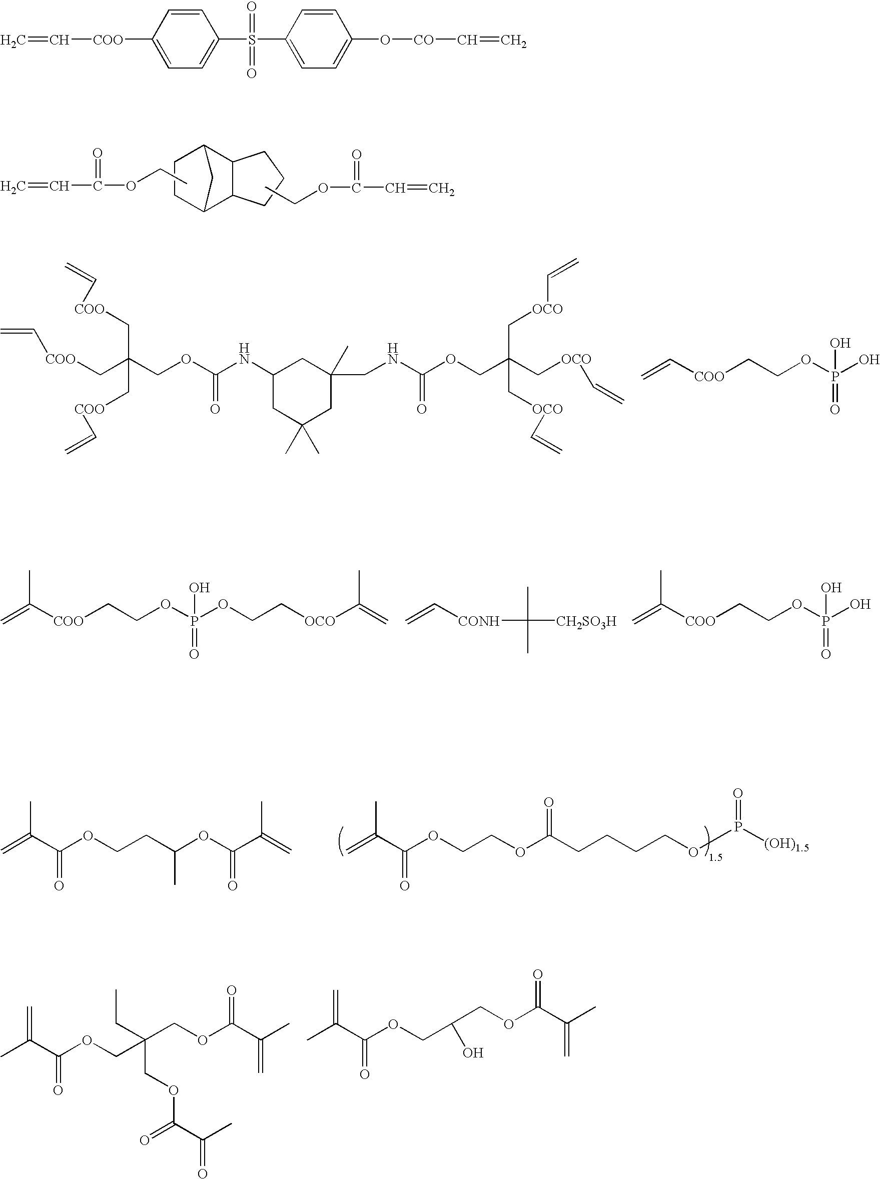

Methods for polymerizing the monomers are not particularly limited and there are preferably used heat polymerization, photo (ultraviolet light, visible light) polymerization, electron beam polymerization, plasma polymerization, and a combination of these. When heat polymerization is carried out, the substrate is required to have a reasonable heat stability. In this case, the glass transition temperature (Tg) of the substrate needs to be higher than the heating temperature.

When photo polymerization is carried out, it is preferable to use a photo polymerization initiator at the same time. The photo polymerization initiators include Irgacure Series products (for example, Irgacure 651, Irgacure 754, Irgacure 184, Irgacure 2959, Irgacure 907, Irgacure 369, Irgacure 379, and Irgacure 819), Darocure Series products (for example, Darocure TPO and Darocure 1173), and Quantacure PDO, which are marketed by Ciba Specialty Chemicals Corp.; and Ezacure Series products (for example, Ezacure TZM and Ezacure TZT) and oligomer-type Ezacure KIP Series products, which are marketed by Sartomer Co., Inc.

The light irradiated is usually ultraviolet light emitted by a high-pressure mercury lamp or a low-pressure mercury lamp. Irradiation energy is preferably 0.5 J/cm² or higher, more preferably 2J/cm² or higher.

In addition, polymerization of the acrylates and methacrylates is inhibited by oxygen in air. Accordingly, in the present invention, when these are used as the monomer layer, it is preferable to lower the oxygen concentration or the partial pressure of oxygen when polymerizing. When the oxygen concentration is lowered by a nitrogen substitution method, the oxygen concentration is preferably 2% or less, more preferably 0.5% or less. When the partial pressure of oxygen is lowered by an evacuation method, the total pressure is preferably 1000 Pa or less, more preferably 100 Pa or less. Also, it is especially preferable to carry out the ultraviolet polymerization under a reduced pressure condition of 100 Pa or less by irradiating an energy of 2 J/cm² or more.

In the present invention, the degree of polymerization of the monomer is preferably 80% or more, more preferably 85% or more, and further preferably 90% or more. Here, the degree of polymerization refers to the proportion of the reacted polymerizable groups among all polymerizable groups (for example, acryloyl groups and methacryloyl groups in case of acrylates and methacrylates) of the monomer mixture.

In the production method of the functional film 10 of the present invention, an especially preferable monomer layer is a film including, as the main component, a polymer having a constituent unit where m is 2 and a constituent unit where m is 3 or larger, in a structural unit represented by the following formula (I).

General formula (I):

(Z—COO)ₘ—L

(in the general formula (I), Z is represented by the following formula (a) or formula (b), wherein R¹ and R² each independently represent a hydrogen atom or a methyl group and the asterisk * represents the position at which formula (a) or formula (b) binds to the carbonyl group in the general formula (I); L represents an m-valent linking group. Also, m number of Zs may be identical to or different from each other but at least one Z is represented by the following formula (a).)

General formulae (a) and (b)

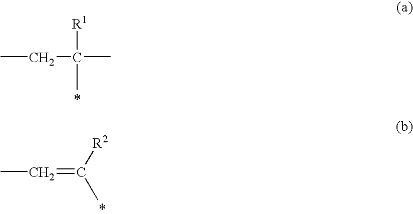

The monomer layer is preferably a film including, as the main component, any one polymer selected from: a polymer having a constituent unit where m is 2 and a constituent unit where m is 3; a polymer having a constituent unit where m is 2 and a constituent unit where m is 4 or larger; and a polymer having a constituent unit where m is 2, a constituent unit where m is 3, and a constituent unit where m is 4 or larger.

Alternatively, the monomer layer may comprise a plurality of these polymers, which as a whole constitute the main component.

L is an m-valent linking group. In the present invention, a carbon number of L is not particularly limited but is preferably 3 to 18, more preferably 4 to 17, further preferably 5 to 16, especially preferably 6 to 15.

When m is 2, L is a bivalent linking group. Examples of such bivalent linking groups include an alkylene group (for example, 1,3-propylene group, 2,2-dimethyl-1,3-propylene group, 2-butyl-2-ethyl-1,3-propylene group, 1,6-hexylene group, 1,9-nonylene group, 1,12-dodecylene group, and 1,16-hexadecylene group), an ether group, an imino group, a carbonyl group, and a bivalent residue in which a plurality of these bivalent groups are linked in series (for example, polyethyleneoxy group, polypropyleneoxy group, propionyloxyethylene group, butyloyloxypropylene group, caproyloxyethylene group, and caproyloxybutylene group). Among these, the alkylene group is preferable.

L may contain a substituent. Examples of substituents which can substitute L include an alkyl group (for example, methyl group, ethyl group, and butyl group), an aryl group (for example, phenyl group), an amino group (for example, amino group, methylamino group, dimethylamino group, and diethylamino group), an alkoxy group (for example, methoxy group, ethoxy group, butoxy group, and 2-ethylhexyloxy group), an acyl group (for example, acetyl group, benzoyl group, formyl group, and pivaloyl group), an alkoxycarbonyl group (for example, methoxycarbonyl group, and ethoxycarbonyl group), a hydroxy group, a halogen atom (for example, fluorine atom, chlorine atom, bromine atom, and iodine atom), and a cyano group. Preferable as a substituent is a group which has no oxygen-containing group for a reason described below, especially preferable being an alkyl group.

That is, when m is 2, L is most preferably an alkylene group which has no oxygen-containing group. By employing such a group, when the present invention is applied to production of a gas barrier film, it becomes possible to make the water vapor permeability of the gas barrier film obtained lower.

When m is 3, L represents a trivalent linking group. Examples of such trivalent linking groups include a trivalent residue obtained by removing any one hydrogen atom from the aforementioned bivalent linking group or a trivalent residue obtained by removing any one hydrogen atom from the aforementioned bivalent linking group and substituting thereat an alkylene group, an ether group, carbonyl group, or a bivalent group obtained by linking these groups in series. Among these, a trivalent residue obtained by removing any one hydrogen atom from the alkylene group and having no oxygen-containing group is preferable. When the present invention is applied to production of a gas barrier film, it becomes possible to make the water vapor permeability of the gas barrier film obtained lower.

When m is 4 or larger, L represents a tetravalent or higher-valent linking group. Examples of such tetravalent or higher-valent linking groups can be cited in the same manner as above. Preferable examples can also be cited in the same manner as above. Especially preferable is a tetravalent residue obtained by removing any two hydrogen atoms from an alkylene group and having no oxygen-containing group. By employing such a group, when the present invention is applied to production of a gas barrier film, it becomes possible to make water vapor permeability of the gas barrier film obtained lower.

In the production method of the present invention, when the polymer which constitutes the monomer layer is a polymer which includes, in the general formula (I), a constituent unit where m is 2 and a constituent unit where m is 3 or larger, the proportion of the constituent unit where m is 2 and/or the constituent unit m is 3 in the polymer is preferably 75 to 95% by mass, more preferably 75 to 90% by mass, further preferably 75 to 85% by mass.

When the polymer which constitutes the monomer layer is a polymer which includes, in the general formula (I), a constituent unit where m is 2 and a constituent unit where m is 3, the proportion of the constituent unit where m is 2 in the polymer is preferably 60 to 80% by mass, more preferably 65 to 75% by mass. On the other hand, the proportion of the constituent unit where m is 3 is preferably 10 to 50% by mass, more preferably 20 to 40% by mass. To keep the proportions in these ranges is preferable because it enables more effective exhibition of a balance between the film hardness and the degree of polymerization.

Also, when the polymer which constitutes the monomer layer is a polymer which includes, in the general formula (I), a constituent unit where m is 2 and a constituent unit where m is 4 or larger, the proportion of the constituent unit where m is 4 or larger in the polymer is preferably 10 to 50% by mass, more preferably 20 to 40% by mass, with, in addition, preferable m being 4.

Further, when the polymer which constitutes the monomer layer is a polymer which includes, in the general formula (I), a constituent unit where m is 2, a constituent unit where m is 3, and a constituent unit where m is 4 or larger, the proportion of the total of the constituent unit where m is 2 and constituent unit where m is 3 in the polymer is preferably 75 to 95% by mass, more preferably 75 to 90% by mass, further preferably 75 to 85% by mass. The proportion of the constituent unit where m is 4 or larger is preferably 5 to 25% by mass, more preferably 10 to 25% by mass, further preferably 15 to 25% by mass.

The aforementioned polymers which constitute the main component of the monomer layer may have structural units not represented by the general formula (I). For example, there may be contained a structural unit formed when an acrylate monomer and methacrylate monomer are copolymerized. In the polymer, the proportion of the structural unit not represented by the general formula (I) is preferably 20% by mass or less, more preferably 15% by mass or less, further preferably 10% by mass or less.

As mentioned above, the monomer layer is a film which includes, as the main component, a polymer having a structural unit represented by the general formula (I). Here, the term “main component” implies that the proportion of the polymer having the structural unit represented by the general formula (I) is 80% by mass or more in the total organic film. Especially, the proportion of the same polymer in the monomer layer is 90% by mass or more.

The polymer having no structural unit represented by the general formula (I), which can be included in the monomer layer, is not particularly limited. However, by way of example, there may be mentioned polyester, a methacrylic acid-maleic acid copolymer, polystyrene, a transparent fluororesin, polyimide, fluorinated polyimide, polyamide, polyamideimide, polyetherimide, cellulose acylate, polyurethane, polyether ketone, polycarbonate, alicyclic polyolefin, polyarylate, polyether sulfone, polysulfone, fluorene ring-modified polycarbonate, alicyclic-modified polycarbonate, and fluorene ring-modified polyester.

The polymer which constitutes the main component of the monomer layer can be prepared by polymerizing a mixture (the monomer mixture) of monomers represented by the following general formula (II) where n is 2 and where n is 3 or larger.

General formula (II):

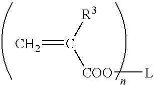

In the general formula (II), R³ represents a hydrogen atom or methyl group; L represents a n-valent linking group. When n is 2 or larger, the respective R³ may be the same or different.

Namely, to put it another way, according to the especially preferable production method using the flash evaporation apparatus 10 of the present invention, the monomer layer is formed on the substrate by polymerizing a monomer mixture containing monomers represented by the general formula (II) where n is 2 and where n is 3 or larger.

Specific examples and a preferable range of L are the same as the examples and the preferred range of L described in relation to the general formula (I). Also, the preferable range of contents of a monomer where n is 2 and a monomer where n is 3 or larger (a monomer where n is 3 and a monomer where n is 4 or larger) is the same as the preferable range of contents of a constituent unit where m is 2 and a constituent unit where m is 3 or larger (a constituent unit where m is 3 and a constituent unit where m is 4 or larger), described in relation to the general formula (I).

In the present embodiment, it is especially preferable to form a monomer layer by polymerizing a monomer mixture containing a monomer where n is 2 and a monomer where n is 3, or by polymerizing a monomer mixture containing a monomer where n is 2 and a monomer where n is 4 or larger, or by polymerizing a monomer mixture containing a monomer where m is 2, a monomer where n is 3, and a monomer where n is 4 or larger. Alternatively, the monomer layer may be formed by carrying out polymerization using a plurality of these monomer mixtures.

In the following, specific examples of monomers where n is 2 or 3 in the general formula (II) are shown but the monomers where n is 2 or 3, which can be used in the present invention, are not limited to these.

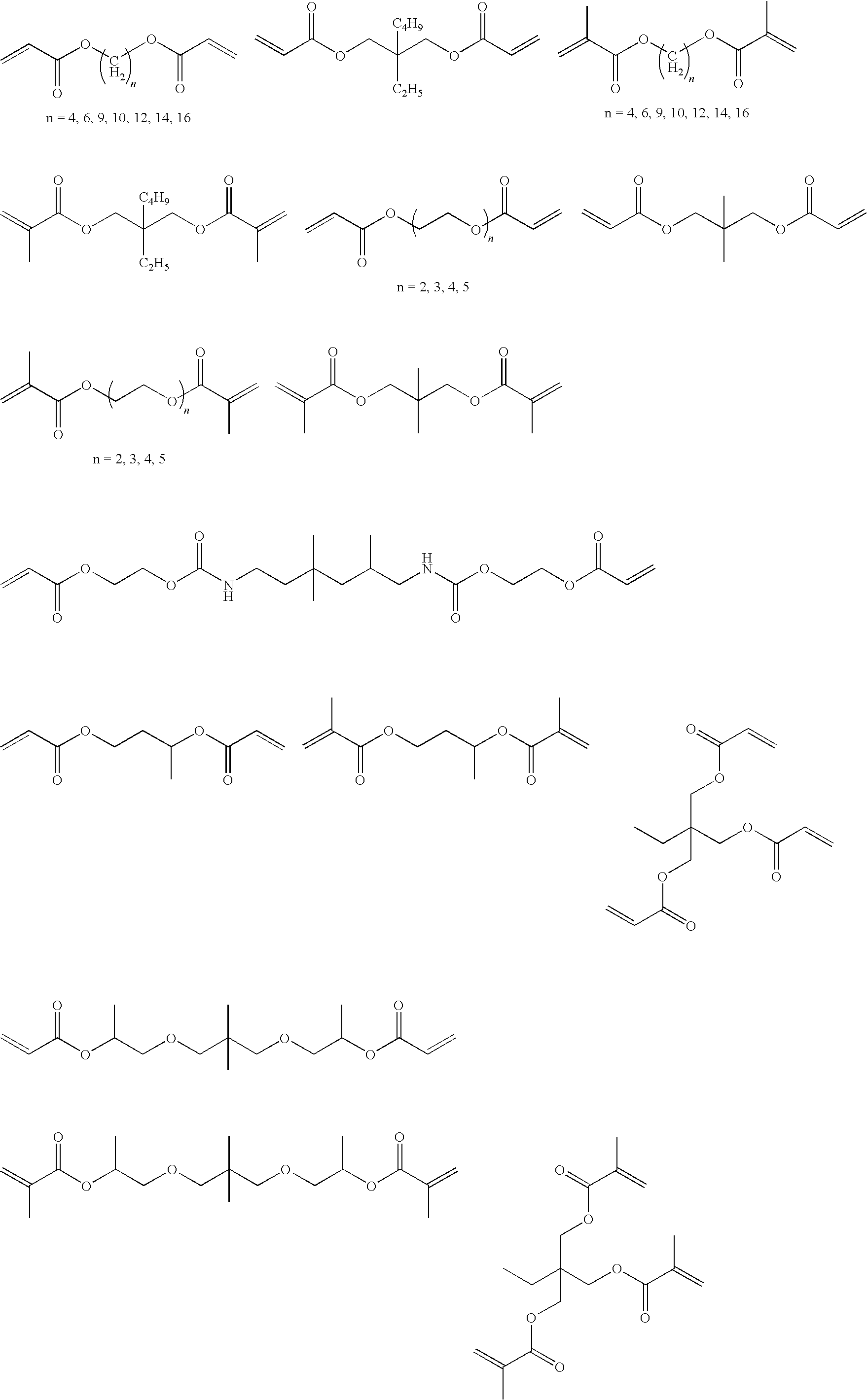

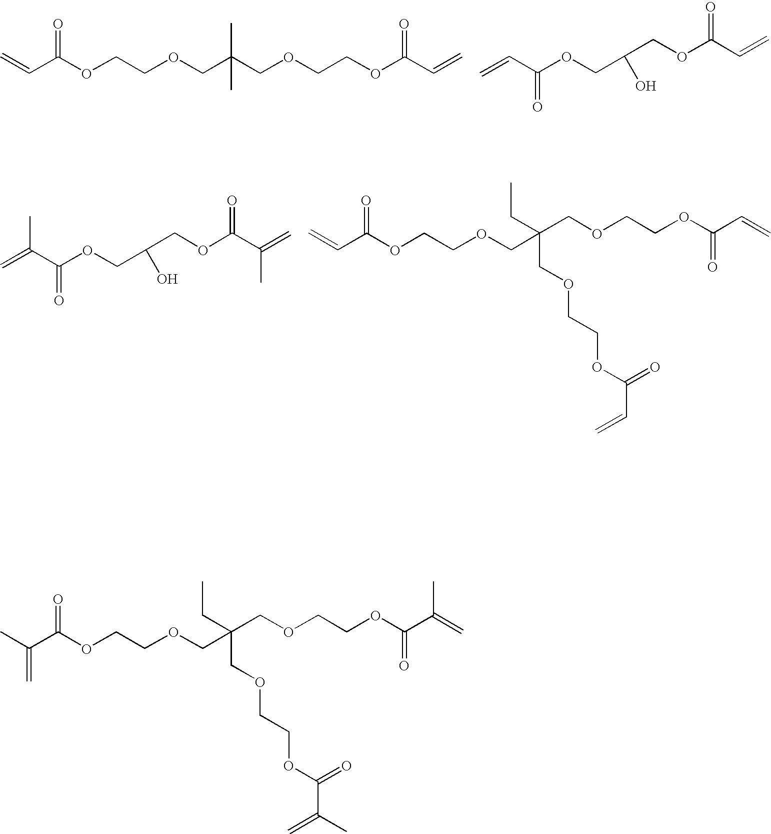

As a monomer represented by the general formula (II) where n is 4 or larger, it is preferable to use a monomer where n is 4 to 6, especially a monomer where n is 4. Specifically, monomers having a pentaerythritol skeleton or a dipentaerythritol skeleton may be mentioned. In the following, specific examples of monomers represented by the general formula (II) where n is 4 or larger are shown, but the monomers where n is 4 or larger, which can be used in the present invention, are not limited to these.

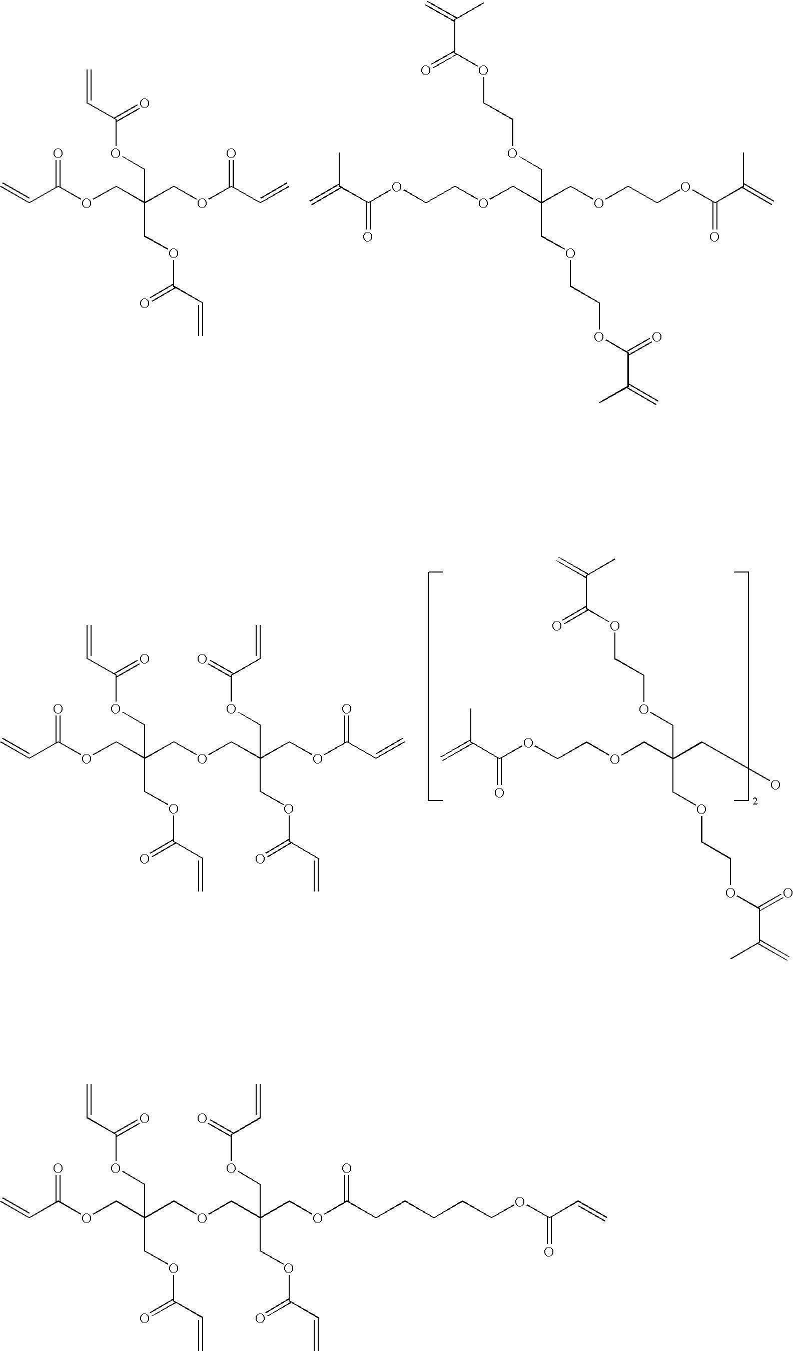

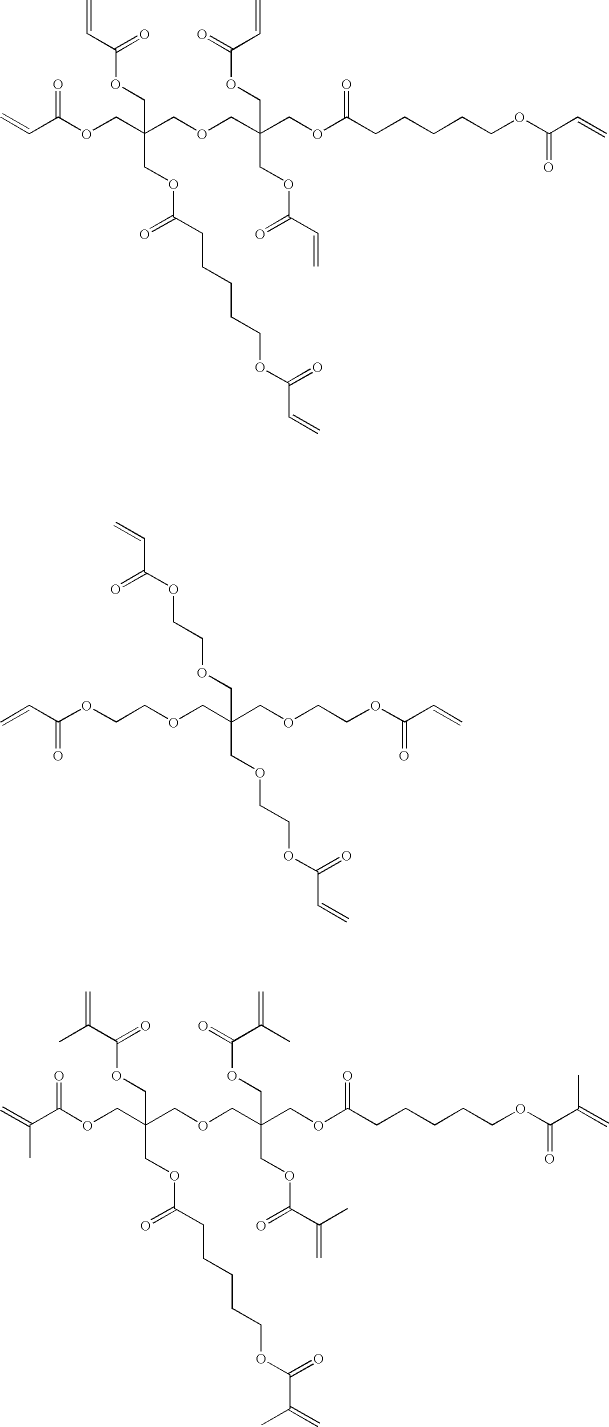

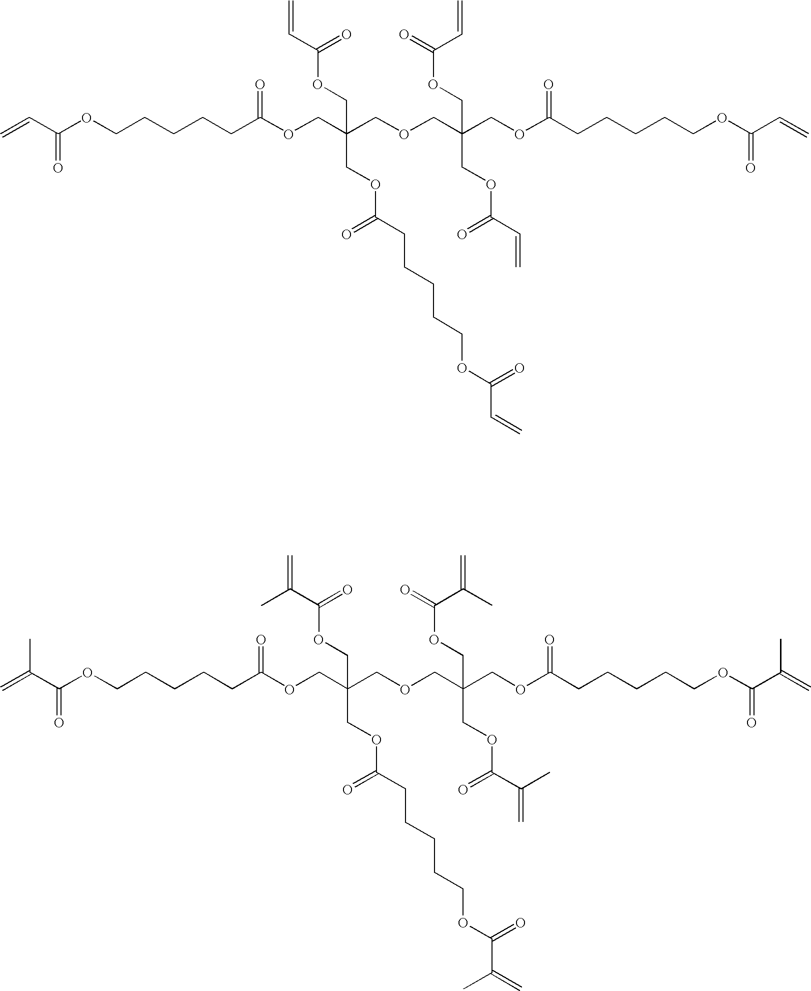

Each monomer mixture can contain only one kind of monomer among the monomers represented by the general formula (II) where n is 2 and where n is 3 or larger (a monomer where n is 3 and a monomer where n is 4 or larger), or can contain two or more kinds of monomers among them.

As described above, in the present embodiment, the harder monomer layer makes it possible to produce a functional film with better characteristics. Especially, it is preferable that the monomer layer has hardness of H or higher, above all, 2 H or higher on the pencil hardness scale.

To increase hardness of the monomer layer, there may be exemplified the following methods:
(1) to increase the degree of polymerization of the monomers,
(2) to use polyfunctional monomers, and
(3) not to use oxygen-containing groups with high flexibility as the linking groups in the monomers.

The degree of polymerization and the number of functional groups are in a relation of trade-off. That is, as the number of functional groups increases, the degree of polymerization decreases. According to a study of the present inventors, the aforementioned mixing proportions of monomers are preferable as a result of our investigation of formulations for increasing the number of functional groups and the degree of polymerization of the monomers. Here, the degree of polymerization is preferably 90% or higher.

In order to form a monomer layer having good hardness, the mixing ratio of the monomers is preferably determined in the following ranges. For example, when, in the monomer mixture, only a monomer where n is 2 and a monomer where n is 3 are used as the monomers represented by the general formula (II), the mix proportion of the monomer where n is 2 is preferably 60 to 80% by mass, more preferably 65 to 75% by mass. The proportion of the monomer where n is 3 is preferably 20 to 40% by mass, more preferably 25 to 35% by mass.

Also, when, in the monomer mixture, only a monomer where n is 2 and a monomer where n is 4 or larger are used as the monomers represented by the general formula (II), the mix proportion of the monomer where n is 2 is preferably 75 to 95% by mass, more preferably 75 to 90% by mass, further preferably 75 to 85% by mass. The mix proportion of the monomer where n is 4 or larger is preferably 5 to 25% by mass, more preferably 10 to 25% by mass, further preferably 15 to 25%.

Further, when, in the monomer mixture, only a monomer where n is 2, a monomer where n is 3, and a monomer where n is 4 or larger are used as the monomers represented by the general formula (II), the total of the mix proportion of the monomers where n is 2 or 3 is preferably 75 to 95% by mass, more preferably 75 to 90% by mass, further preferably 75 to 85% by mass. The mix proportion of the monomer where n is 4 or larger is preferably 5 to 25% by mass, more preferably 10 to 25% by mass, further preferably 15 to 25% by mass.

In the monomer mixture which forms the monomer layer, there may be contained a monomer which is not represented by the general formula (II). However, because these monomers work as an obstacle to the purpose of increasing the hardness of the monomer layer, the amount thereof in the monomer mixture is preferably 20% by mass or less.

The monomers not represented by the general formula (II) include, for example, a monofunctional monomer, preferably a monofunctional acrylate monomer and a monofunctional methacrylate monomer. The molecular weight of the mono-functional acrylate monomer and the monofunctional methacrylate monomer are not particularly limited but usually those with a molecular weight of 150 to 600 are used. Only one or two or more of these monomers may be contained in the monomer mixture. The monofunctional monomer has the effect of increasing the degree of polymerization but when its content is too high, the hardness of the organic layer formed is diminished. Thus, as previously mentioned, the content percentage thereof is preferably less than 20% by mass or less. The more preferable range is the same as the preferable range of the structural unit not represented by the general formula (I).

In the following, preferable specific examples of the monofunctional monomers are shown but the monofunctional monomers which can be used in the present invention are not limited to these.

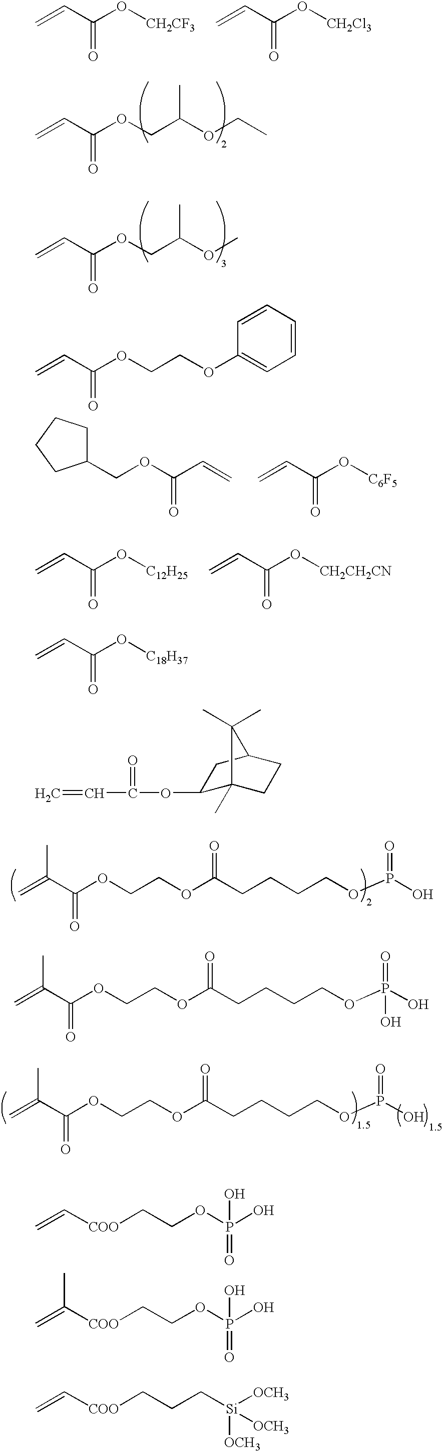

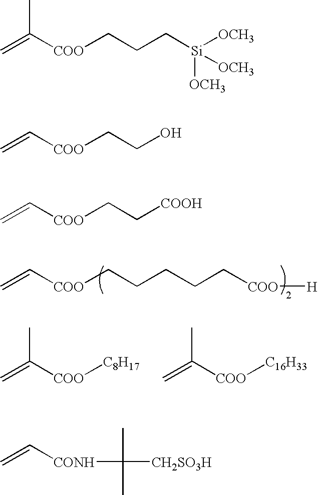

The monomer mixture which forms the monomer layer may contain a phosphate-type (meth)acrylate monomer or a silane coupling group-containing (meth)acrylate monomer in order to improve adhesion. These monomers are added in amounts which correspond to the aforementioned range of amounts depending on the number of functional groups thereof.

In the following, preferable specific examples of a phosphate-type monomer or a silane coupling group-containing monomer are shown but the monomers which can be used in the present invention are not limited to these.

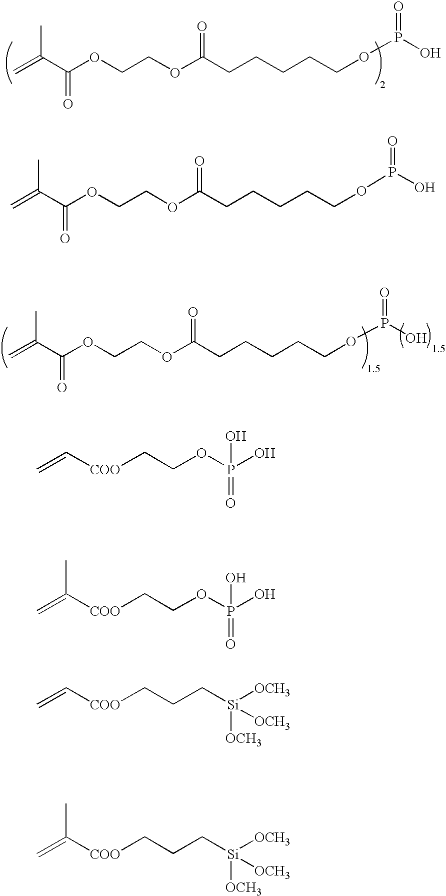

The above-described monomers are combined suitably, vaporized by respective evaporators, and flash evaporated onto a film, thus enabling two or more monomers to be mixed easily.

What is claimed is:

1. A method for flash evaporation, comprising:
continuously conveying a substrate;
feeding a plurality of kinds of monomers prepared in liquid states to separate evaporators;
vaporizing the respective monomers in the separate evaporators and discharging the respective vaporized monomers from the evaporators; and
merging the vaporized monomers and feeding the merged monomers to the substrate for deposition.

2. The method for flash evaporation according to claim 1, further comprising
mixing the monomers after the merging.

3. The process of flash evaporation according to claim 2, wherein, the mixing is performed using a static mixer or a dynamic mixer.

4. An apparatus for flash evaporation, comprising:
a reaction chamber;
a drum disposed inside the reaction chamber to support a continuously conveyed substrate;
a first evaporator;
a first tank which is connected to the first evaporator and holds a first monomer in liquid state therein;
a first pump for feeding the first monomer from the first tank to the first evaporator;
a second evaporator;
a second tank which is connected to the second evaporator and holds a second monomer whose kind is different from that of the first monomer, in liquid state therein;
a second pump for feeding the second monomer from the second tank to the second evaporator;
a merging section for merging the vaporized first and second monomers which are discharged from the first and second evaporators; and
a nozzle disposed facing the drum and connected to the merging section.

5. The apparatus for flash evaporation according to claim 4, further comprising a mixer connected between the nozzle and the merging section.

6. The apparatus for flash evaporation according to claim 5, wherein the mixer is a static mixer or a dynamic mixer.
